(19) United States
(12) Patent Application Publication
(10) Pub. No.: US 2024/0429145 A1
(43) Pub. Date: Dec. 26, 2024

(54) BUILDING MULTI-DIE FPGAS USING CHIP-ON-WAFER TECHNOLOGY

(71) Applicant: XILINX, INC., San Jose, CA (US)

(72) Inventors: Praful JAIN, San Jose, CA (US); Brian C. GAIDE, Erie, CO (US); Martin L. VOOGEL, Niwot, CO (US)

(21) Appl. No.: 18/214,381

(22) Filed: Jun. 26, 2023

(51) Int. Cl. H01L 23/498; H01L 23/00; H01L 23/538; H01L 25/065

(52) U.S. Cl. CPC H01L 23/49816; H01L 23/49827; H01L 23/5386; H01L 24/16; H01L 24/32; H01L 24/73; H01L 25/0657; H01L 2224/16146; H01L 2224/73204; H01L 2225/06513; H01L 2225/06541; H01L 2924/1431

(57) ABSTRACT

Embodiments herein describe techniques to build multi-die field-programmable gate arrays (FPGAs) using chip-on-wafer (CoW) technology. In an embodiment, FPGA chiplets (i.e., dies) and an interposer substrate include respective hybrid bonding connectors. Metal layers of the interposer substrate are patterned to provide inter-die communications amongst the multiple dies via the hybrid bonding connectors, and the dies communicate with one another via the hybrid bonding connectors using a non-serialized protocol native to the FPGA. The dies may communicate with one another through edge-based hybrid bonding connectors (e.g., in a symmetrical fashion). The metal layers of the interposer substrate may also support intra-die communications (e.g., data, clocks, and/or controls) and/or provide power, clock(s), and/or configuration parameters to the dies via hybrid bonding connectors within central regions of the dies. The IC device may include more than 1000 tracks per millimeter (e.g., more than 1600, 2800, 3500, or greater).

### TECHNICAL FIELD

Examples of the present disclosure generally relate to techniques to build multi-die field-programmable gate arrays (FPGAs) using chip-on-wafer (CoW) technology.

### BACKGROUND

As integrated circuit (IC) dies become larger, more complex, and more densely packed, fabrication costs increase and yields decrease.

Theoretically, a relatively complex, dense IC die (e.g., a field-programmable gate array, or FPGA) could be re-designed as multiple IC dies mounted on a substrate. with appropriate chip-to-chip (C2C) interconnections. In some situations, however, the vast number of C2C interconnections needed for a multi-die design cannot be accommodated with conventional C2C capabilities, without incurring significant costs in terms of overall area requirements, additional circuitry, power consumption, and other cost factors.

### SUMMARY

Techniques for building multi-die field-programmable gate arrays (FPGAs) using chip-on-wafer (CoW) technology are described. One example is an integrated circuit (IC) device that includes an interposer substrate having a plurality of metal layers, a plurality of hybrid bonding connectors exposed through a surface of the interposer substrate, and electrical connections between the hybrid bonding connectors of the interposer substrate and the patterned metal layers. The IC device further includes a field-programmable gate array (FPGA) distributed amongst multiple dies disposed face-down on the surface of the interposer substrate. As used herein, the term “face” refers to a surface of a die closest to metal layers of the die, and the term “active layer” refers to a layer of a die that includes circuitry. The active layer(s) of a die is typically positioned between the metal layers and a substrate of the die.

The multiple dies include respective hybrid bonding connectors exposed through surfaces (i.e., faces) of the respective dies in alignment with the hybrid bonding connectors of the interposer substrate. The metal layers are patterned to provide inter-die communications amongst the multiple dies, and the dies communicate with one another via the hybrid bonding connectors of the respective dies and the hybrid bonding connectors, patterned metal layers, and electrical connections of the interposer substrate, using a non-serialized protocol native to the FPGA.

Another example described herein is an IC device that includes an interposer substrate having a plurality of metal layers, a plurality of hybrid bonding connectors exposed through a surface of the interposer substrate, and electrical connections between the hybrid bonding connectors of the interposer substrate and the one or more metal layers. The IC device further includes multiple Dies disposed face-down on the surface of the interposer substrate. The Dies include respective hybrid bonding connectors exposed through faces of the respective Dies in alignment with the hybrid bonding connectors of the interposer substrate. The metal layers are patterned to provide inter-die communications amongst the multiple Dies. A first one of the Dies includes components of FPGA and communicates with one or more other ones of the Dies via the hybrid bonding connectors of the respective Dies and the hybrid bonding connectors, electrical connections, and patterned metal layers of the interposer substrate, using a non-serialized protocol native to the FPGA.

Another example described herein is an IC device that includes an interposer substrate having a plurality of metal layers, a plurality of hybrid bonding connectors exposed through a surface of the interposer substrate, and electrical connections between the hybrid bonding connectors of the interposer substrate and the patterned metal layers. The IC device further includes a plurality of field-programmable gate array (FPGA) chiplets disposed face-down on the surface of the interposer substrate. The FPGA chiplets include respective hybrid bonding connectors exposed through faces of the respective FPGA chiplets in alignment with the hybrid bonding connectors of the interposer substrate. The metal layers are patterned to provide inter-die communications amongst the FPGA chiplets, and the FPGA chiplets communicate with one another via the hybrid bonding connectors of the respective FPGA chiplets and the hybrid bonding connectors, patterned metal layers, and electrical connections of the interposer substrate, using a non-serialized protocol native to the FPGA chiplets.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 is a perspective view of an IC device that includes multiple dies that communicate with one another via patterned metal layers of an interposer substrate and hybrid bonding connectors, according to an embodiment

FIG. 2 is a plan view of the IC device, illustrating hybrid bonding connectors of the dies that are exposed through faces of the dies, according to an embodiment.

FIG. 3 is a cross-sectional side view of the IC device, illustrating the hybrid bonding connectors of the dies, hybrid bonding connectors exposed through a surface of the interposer substrate, metal layers of the interposer substrate, and electrical connections (e.g., metal filled vias) amongst the hybrid bonding connectors and the metal layers, according to an embodiment.

FIG. 4 is a plan view of the IC device in which the hybrid bonding connectors of the dies include hybrid bonding connectors along one or more edges of the faces of the dies, and hybrid bonding connectors within inner regions of the faces of the dies, according to an embodiment.

FIG. 5 is a cross-sectional side view of the IC device, as illustrated in FIG. 4, in which the hybrid bonding connectors along the edges of the faces of the dies are used for inter-die communications, and the hybrid bonding connectors within the inner regions of the faces of the dies are used for intra-die connections and/or to provide power, a clock(s), and/or configuration parameters to the dies, according to an embodiment.

FIG. 6 is a cross-sectional side view of the IC device, further including a die embedded within the interposer substrate, according to an embodiment.

FIG. 7 is a cross-sectional side view of an IC assembly that includes the IC device, a package substrate, and a circuit board, according to an embodiment.

FIG. 8 is a perspective view of an IC device that includes multiple instances of the IC device of FIG. 1, that communicate with one another via a super interposer substrate, according to an embodiment.

FIG. 9 is a cross-sectional side view of the IC device of FIG. 8, in which the super interposer substrate includes one or more metal layers and electrical connections between the metal layers and μbumps, according to an embodiment.

FIG. 10 is a cross-sectional side view of an IC device that includes the IC device as illustrated in FIG. 5, the super interposer substrate of FIGS. 8 and 9, and a region in which another IC device may be mounted (e.g., a high-bandwidth memory (HBM) device or other 3^{rd} party IC device), according to an embodiment.

FIG. 11 is a perspective view of an IC device that includes a 4×2 arrangement of dies that communicate with one another via an interposer substrate, according to an embodiment.

FIG. 12 is a block diagram of a configurable circuitry, including an array of configurable or programmable circuit blocks or tiles, according to an embodiment.

FIG. 13 is a plan view of an IC device in which a FPGA (e.g., configurable circuitry of FIG. 12) is distributed amongst multiple heterogeneous FPGA chiplets that communicate with one another via hybrid bonding connectors and patterned metal layers of an interposer substrate, in a protocol (e.g., a non-serialized protocol) that is native to the FPGA, according to an embodiment.

FIG. 14A is a cross-sectional side view of a portion of a die and a portion of a substrate that include respective hybrid bonding connectors embedded within a non-conductive material, according to an embodiment.

FIG. 14B is a cross-sectional side view of an IC device in which the die and substrate of FIG. 14A are bonded to one another, according to an embodiment.

FIG. 15 is a circuit diagram of die 102-1 that includes an input/output (IO) circuit 1502 that permits a circuit block of the die to communicate with another circuit block of the die and/or with an off-die device (e.g., another die) via a hybrid bonding connector, using a non-serialized protocol native to the circuit block, according to an embodiment.

FIG. 16 is a block diagram of the IC device, as illustrated in FIG. 5, in which dies include multiple circuit blocks and associated IO circuits, according to an embodiment.

FIG. 17 is a block diagram of an IC device that includes a die having a functional circuit that communicates with adjacent dies in a symmetrical fashion, via an IO circuit and hybrid bonding connectors, according to an embodiment.

FIG. 18 is an expanded view of the die of FIG. 17, according to an embodiment.

FIG. 19 is a circuit diagram of the IO circuit of FIG. 17, according to an embodiment.

FIG. 20A is a block diagram of a set of dies that includes a core die (e.g., a FPGA die), a first peripheral die (e.g., an IO die), and a second peripheral die (e.g., a gigabit transceiver or GT die), according to an embodiment.

FIG. 20B is a block diagram of an IC device that includes one core die, one first peripheral die, and one second peripheral die, interconnected via an interposer substrate, according to an embodiment.

FIG. 20C is a block diagram of an IC device that includes four core dies, four first peripheral dies, and four second peripheral dies, interconnected via an interposer substrate, according to an embodiment.

FIG. 20D is a block diagram of an IC device that includes three core dies, three first peripheral dies, and two second peripheral dies, interconnected via an interposer substrate, according to an embodiment.

FIG. 20E is a block diagram of an IC device that includes two core dies, two first peripheral dies, and one second peripheral die, interconnected via an interposer substrate, according to an embodiment.

FIG. 20F is a block diagram of an IC device that includes four core dies, four first peripheral dies, and two second peripheral dies, interconnected via an interposer substrate, according to an embodiment.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the features or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

An integrated circuit (IC) die is a small block of semiconducting material on which functional circuitry is fabricated. Typically, multiple instances of a circuit design are fabricated on a wafer of electronic-grade silicon (EGS) or other semiconductor material, such as gallium-arsenide (GaAs). The wafer is then cut, or diced to separate the individual circuit designs into respective dies, or dice.

A multi-chip module (MCM) is an IC device in which multiple dies are integrated on a substrate. A MCM may include multiple dies arranged side-by-side on an interposer substrate (i.e., a substrate that provides inter-die, or chip-to-chip (C2C) connections). Such a MCM may be referred to as a 2.5 dimensional (2.5D) IC device and/or a chip-on-wafer (CoW) IC device. Where the interposer substrate is attached to a package substrate, the MCM may be referred to as a chip-on-wafer-on-substrate (CoWoS) IC device.

A 2.5D IC device may include bumps (e.g., solder bumps) that provide electrical contacts between a die and the interposer substrate, and between the interposer substrate and the package substrate. Solder bumps between a die and the interposer substrate may be relatively small, and may be referred to as micro-bumps (μbumps) or C4 bumps. Solder bumps between the interposer substrate and the package substrate may be relatively large, and may be referred to as package bumps. Bumps range in size, or pitch (i.e., the distance between centers of adjacent bumps). from 40-μm pitches to as small as 10-μm pitches. Bump pitches below 10-μm are not technically feasible, which limits the density of inter-die, or chip-do-chip (C2C) connections.

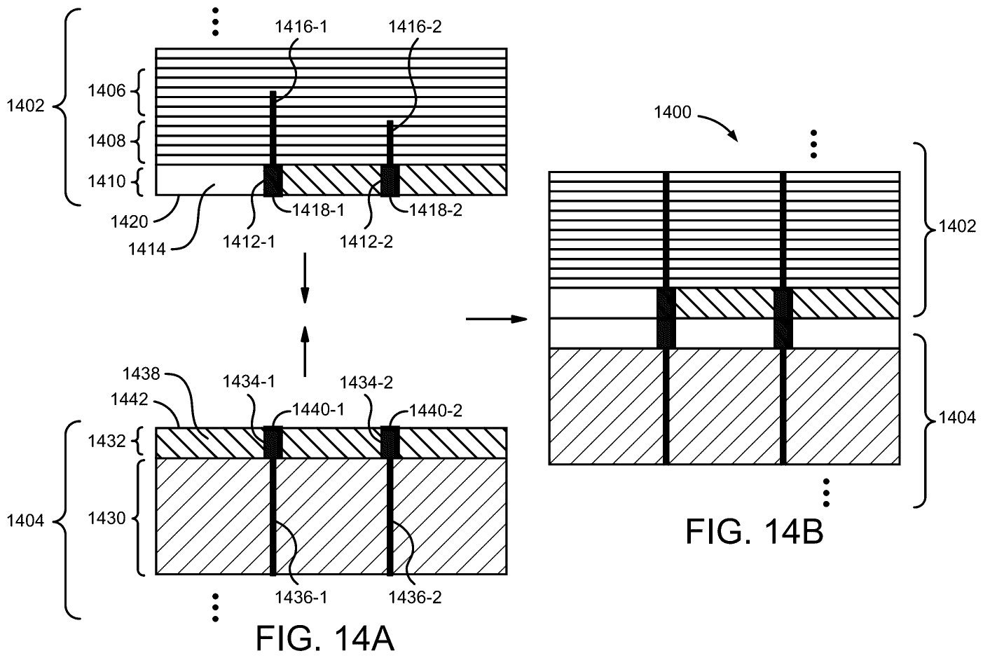

Hybrid bonding techniques provide higher-density C2C solutions than what is currently available with bumps. Hybrid bonding techniques utilize closely spaced metal pillars (e.g., 10 um and below) to vertically connect die-to-wafer (D2W) or wafer-to-wafer (W2W). Hybrid bonding may be useful to provide face-to-face connections of dies to interposer substrates. Example hybrid connections are provided further below with reference to FIG. 14.

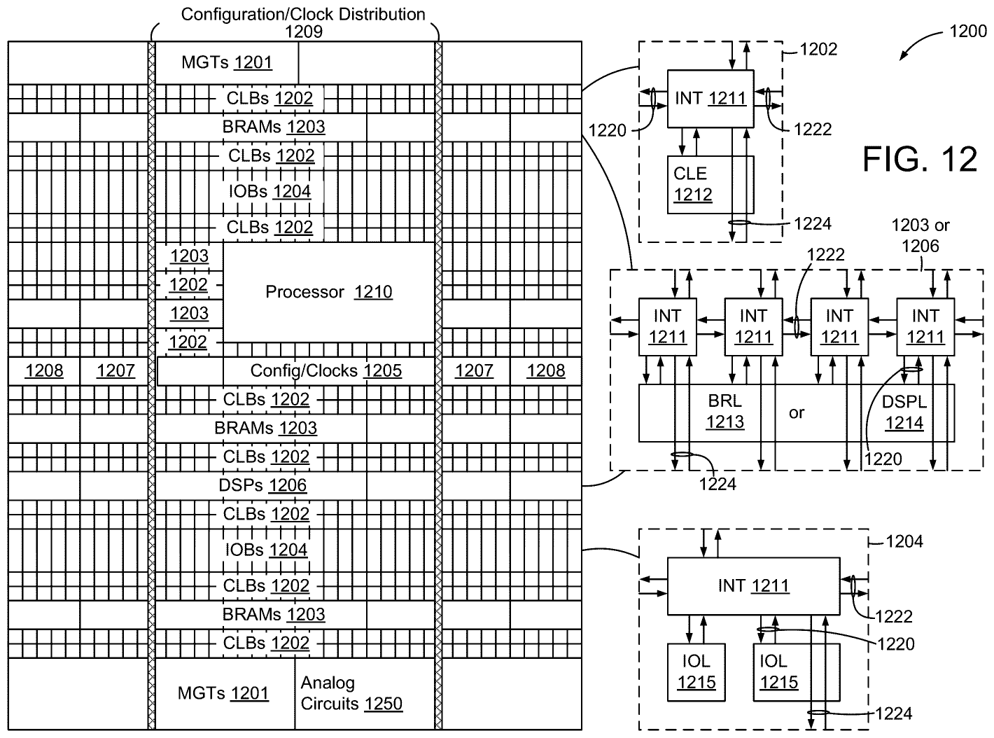

A field-programmable gate array (FPGA) is an electrically-configurable/reconfigurable integrated circuit. A FPGA may include an array of programmable logic blocks, and a hierarchy of reconfigurable interconnects amongst the logic blocks. The logic blocks can be configurable to perform relatively simple logic functions (e.g., AND and XOR) and/or relatively complex combinational functions. A FPGA may further include memory elements, such as registers, flip-flops, and/or memory, such as random-access memory (RAM), dynamic RAM (DRAM), and/or read-only memory (ROM). A FPGA may further include an embedded processor and input/output (IO) circuitry, such as a multi-gigabit transceiver and/or a serializer/deserializer (SERDES). A FPGA may be configured, or programmed by loading configuration parameters into configuration registers (CRs) of the FPGA. The configuration parameters may be provided by an external tool based on a configuration file, which may be provided in a hardware description language (HDL), such as a Verilog HLD (VHDL), currently standardized by the Institute of Electrical and Electronics Engineers (IEEE) as IEEE standard 1800-2017. An example FPGA is provided further below with reference to FIG. 12.

As the industry scales to more advanced technology nodes, and as FPGA complexity grows, die size and yield become increasingly significant factors. It would be useful to distribute a FPGA over multiple smaller interconnected dies (i.e., chiplets), as this would increase yield and decrease cost. Distributing a FPGA over multiple dies necessitates a vast number of C2C interconnections, which raises technical challenges. One challenge is that conventional C2C technology limits C2C connections to approximately 1000 tracks per millimeter, which presents area and routing challenges. C2C congestion could be reduced by serializing, and possibly interleaving C2C communications, such as with serializer/deserializer (SERDES) circuitry. However, SERDES circuitry is expensive, in terms of components, power consumption, and area requirements, and may increase latency. Another challenge is track lengths between chiplets, which may increase latency. Another challenge is clock skew that results from resistive/capacitive (RC) effects that arise when a clock track is too close to other tracks within a die.

Embodiments herein describe techniques to build multi-die field-programmable gate arrays (FPGAs) using chip-on-wafer (CoW) technology.

Embodiments herein may be used to distribute a FPGA over multiple chiplets that communicate with one another using a non-serialized communication protocol native to the FPGA circuitry.

Embodiments herein (e.g., hybrid bonding based C2C interconnections in combination with an interposer substrate, or chip-on-wafer (CoW) hybrid bonding) may be useful to increase C2C interconnect densities, such as to provide C2C interconnections that equal or exceed track densities of vertically stacked FPGA chiplets, and that equal or exceed (e.g., by 50% or more) current horizontal pin densities, Embodiments herein may be useful to provide more than 1000 tracks per millimeter (e.g., more than 1600 tracks per millimeter, more than 2800 tracks per millimeter, more than 3500 tracks per millimeter, and beyond). Increasing C2C interconnect density may be useful to permit FPGA chiplets to communicate with one another using a native (e.g., non-serialized) protocol of the FPGA circuitry, and thus maximize chip-size reduction, power savings, and/or other cost savings. In an embodiment, CoW in combination with hybrid bonding may provide C2C interconnect densities that are between 20 and 40times greater than what is currently available with μbumps.

Embodiments herein (I.e., edge-based C2C hybrid bonding connectors) may be useful to reduce inter-die track lengths, and thus latency.

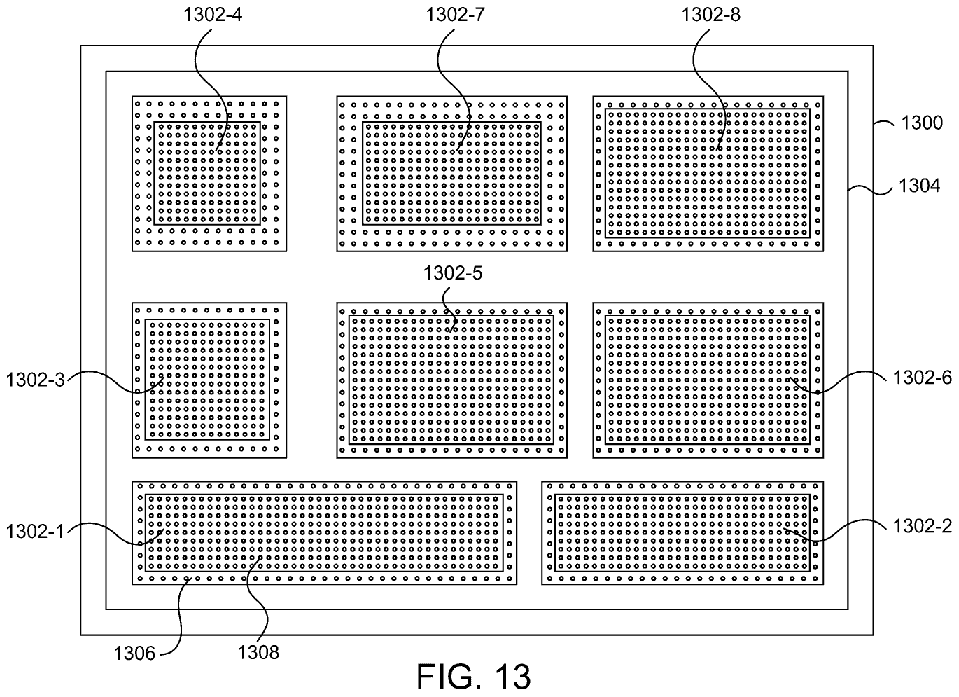

Embodiments herein may be useful to reduce clock skew, such as by routing a clock from one node of a die, downward to and through an interposer substrate (i.e., where congestion may be lower), and back up to another node of the die. Example FPGA chiplets are provided further below with reference to FIG. 13.

Embodiments herein may be useful to decrease chip size, and thus increase yield and reduce overall costs. Embodiments herein may be implemented without a reconstituted wafer, which may reduce costs associated with stacked dies. Where yield of an interposer substrate (described further below) is a concern, a reconstituted wafer may be used.

Embodiments herein may be useful to increase routing options for a routing compiler.

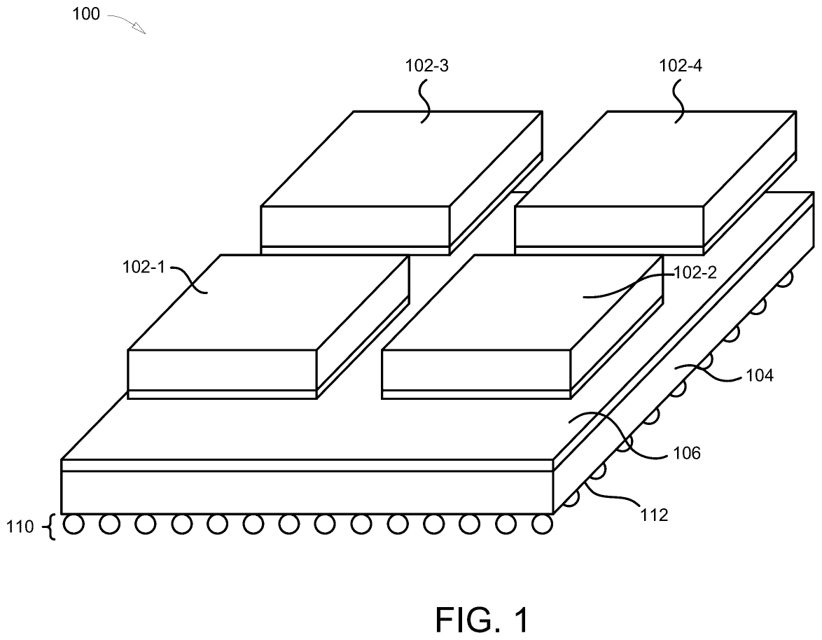

FIG. 1 is a perspective view of an IC device 100 that includes multiple dies/dice 102-1 through 102-4 (collectively, dies 102), that communicate with one another via patterned metal layers of an interposer substrate 104 and hybrid bonding connectors, according to an embodiment. Dies 102 may include homogenous dies, heterogeneous dies, or a combination thereof. Dies 102 may represent respective portions of a FPGA (i.e., FPGA chiplets). Dies 102, or a subset thereof, may have substantially similar physical dimensions. Dies 102, or a subset thereof, may have dissimilar physical dimensions. Dies 102, or a subset thereof, may be fabricated in accordance with a fabrication process of 7 nanometer fabrication process or a smaller fabrication process (e.g., a 3 nanometer (N3) fabrication process, or an enhanced N3 (N3E) fabrication process). Dies 102 are not, however, limited to the foregoing fabrication processes.

In the example of FIG. 1, dies 102 are positioned face-down on a surface 106 of interposer substrate 104. Dies 102 and interposer substrate 104 may include respective hybrid bonding connectors that provide electrical connections between dies 102 and interposer substrate 104, examples of which are provided further below.

IC device 100 may further includes bumps (e.g., μbumps, or C4 bumps) 110 distributed across a second surface 112 of interposer substrate 104 that provide electrical connections between interposer substrate 104 and a package substrate. Interposer substrate 104 may include an electrically insulating, or non-conductive material such as, without limitation, silicon dioxide.

Dies 102 may be referred to as super logic regions (SLRs), and IC device 100 may be referred to as a chip-on-wafer (CoW) IC device.

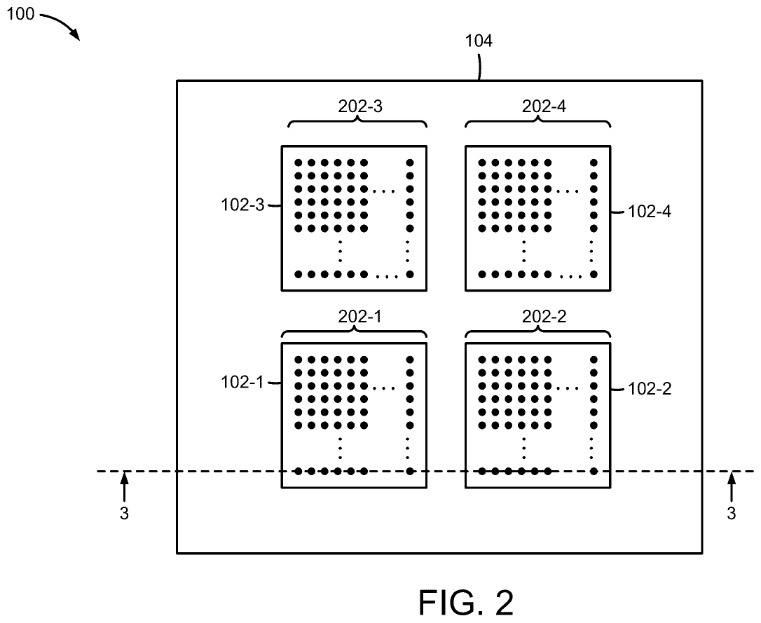

FIG. 2 is a plan view of IC device 100, illustrating hybrid bonding connectors 202 of dies 102 that are exposed through faces of dies 102, according to an embodiment.

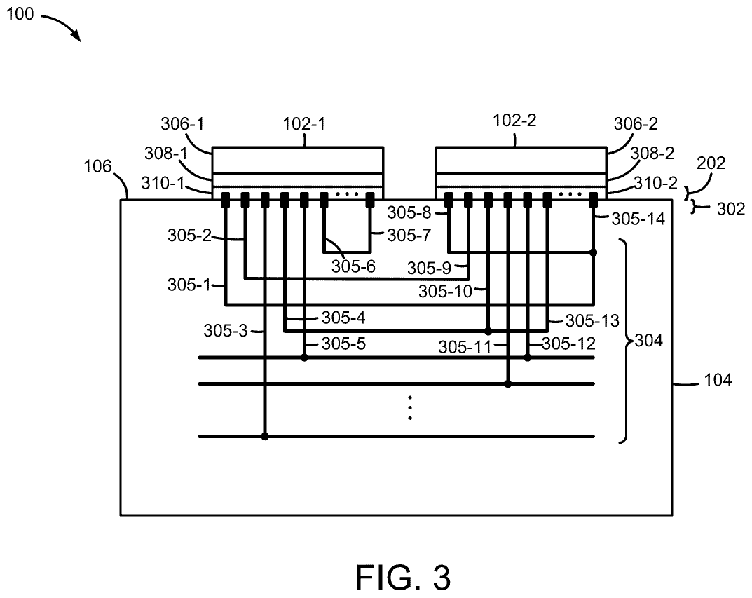

FIG. 3 is a cross-sectional side view of IC device 100, illustrating hybrid bonding connectors 202 of dies 102, hybrid bonding connectors 302 exposed through surface 106 of interposer substrate 104, metal layers 304 of interposer substrate 104, and electrical connections 305 (e.g., metal filled vias) amongst hybrid bonding connectors 302 and metal layers 304, according to an embodiment.

Metal layers 304 may be patterned to provide inter-die connections amongst two or more dies 102. Metal layers 304 may be further patterned to provide intra-die connections within respective dies 102. Intra-die connections may be useful to route data/communications and/or a clock(s) within a die 102. An intra-die connection for data/communications may be useful to reduce congestion within a die 102 and/or reduce a travel distance for the data or clock. An intra-die connection for a clock may further be useful to avoid/reduce clock skew that might otherwise result from RC effects caused by relatively narrow distances between a clock trace and other traces within the die 102. Metal layers 304 may be further patterned to provide power, a clock(s), and/or configuration parameters to one or more dies 102. Metal layers 304 may be patterned to distribute the power and/or the clock(s) to multiple nodes of a die 102.

In the example of FIG. 3, dies 102-1 and 102-2 include respective substrates 306-1 and 306-2, active layers (i.e., circuitry) 308-1 and 308-2, and metal layers 310-1 and 310-2.

In an embodiment, hybrid bonding connectors 202 and 302 have pitches of approximately 10 μ, or less. In an embodiment, patterned metal layers 304 of interposer substrate 104 include more than 1000 tracks per millimeter (e.g., more than 1600 tracks per millimeter, more than 2800 tracks per millimeter, more than 3500 tracks per millimeter, and beyond). In an embodiment, hybrid bonding connectors 202 and 302 and patterned metal layers 304 of interposer substrate 104 are configured to provide more than 1000 inter-die (i.e., C2C) connections per millimeter (e.g., more than 1600 tracks per millimeter, more than 2800 tracks per millimeter, more than 3500 tracks per millimeter, and beyond).

The relatively small pitches of hybrid bonding connectors 202 and 203 permit routing of relatively significant numbers of intra-die connections through interposer substrate 104, which may reduce on-die congestion and/or reduce area requirements of dies 102. As hybrid bonding techniques improve, even greater numbers of intra-die connections may be routed through interposer substrate 104.

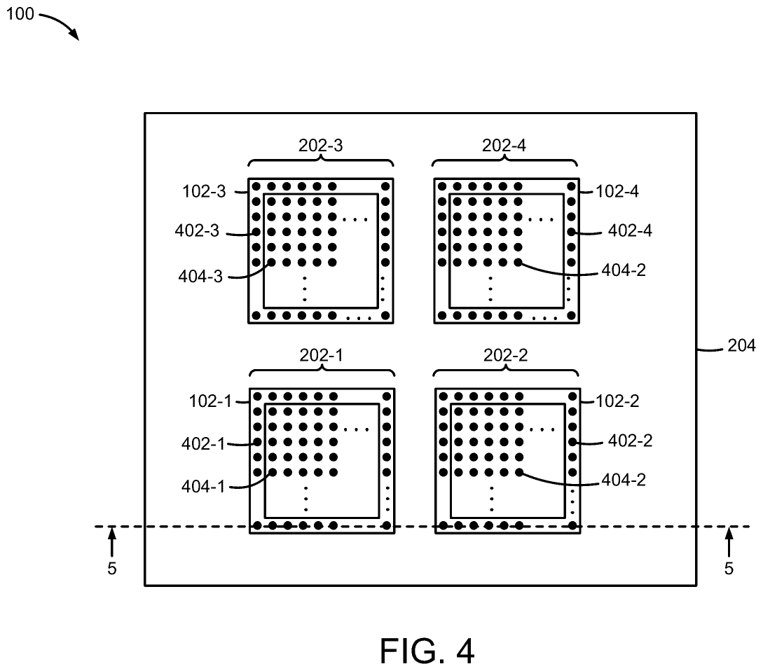

FIG. 4 is a plan view of IC device 100, in which hybrid bonding connectors 202 of dies 102 include hybrid bonding connectors 402 along one or more edges of the faces of dies 102, and hybrid bonding connectors 404 within inner regions of the faces of dies 102, according to an embodiment.

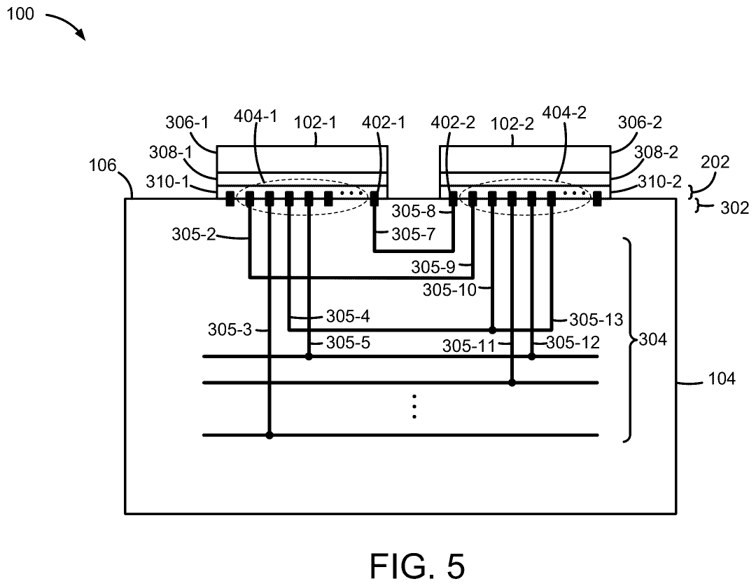

FIG. 5 is a cross-sectional side view of IC device 100, as illustrated in FIG. 4, in which hybrid bonding connectors 402 along edges of the faces of dies 102 are used for inter-die communications, and hybrid bonding connectors 404 within the inner regions of the faces of dies 102 are used for intra-die connections and/or to provide power, a clock(s), and/or configuration parameters to dies 102, according to an embodiment.

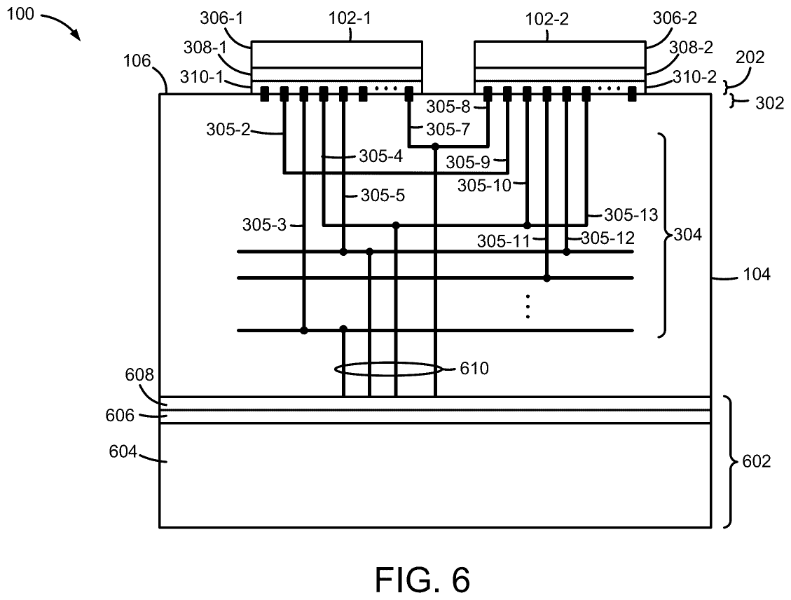

FIG. 6 is a cross-sectional side view of IC device 100, further including a die 602 embedded within interposer substrate 104, according to an embodiment. Die 602 includes a substrate 604, active layers 606, and metal layers 608. Active layers 606 may include active circuits for implementing relatively basic functions, such as memory banks, input/output functions, and/or analog functions. In the example of FIG. 6, interposer substrate 104 may be referred to as an active interposer. In the example of FIG. 6. IC device 100 further includes connections 610 that provide connections between metal layers 608 of die 602 and metal layers 304, die 102-1, and/or die 102-2.

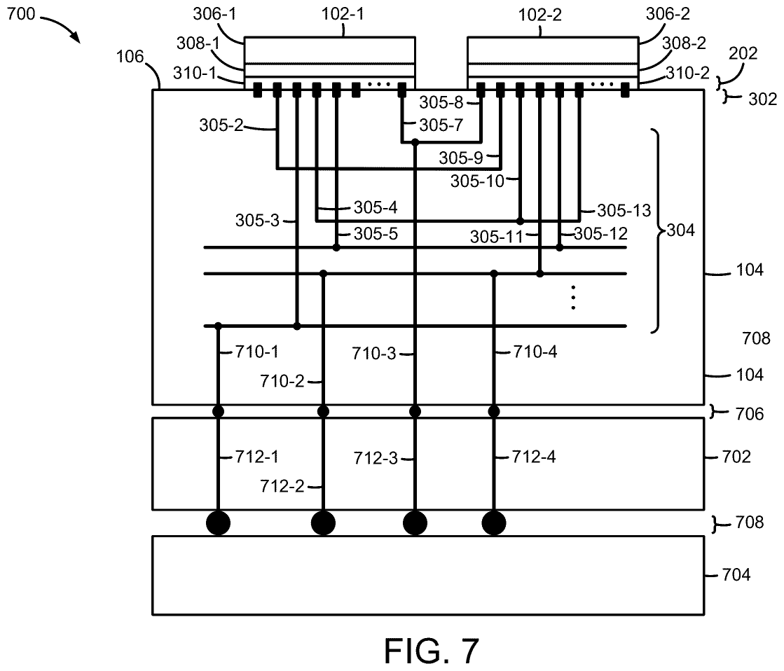

FIG. 7 is a cross-sectional side view of an IC assembly 700 that includes IC device 100, a package substrate 702, and a circuit board 704, according to an embodiment. In the example of FIG. 7, IC assembly 700 further includes μbumps 706 and circuit balls 708, interposer substrate 104 further includes electrical connections 710 (e.g., metal filled vias) between metal layers 304 and μbumps 706, and package substrate 704 includes electrical connections 712 (e.g., metal filled vias) between μbumps 706 and package balls 712.

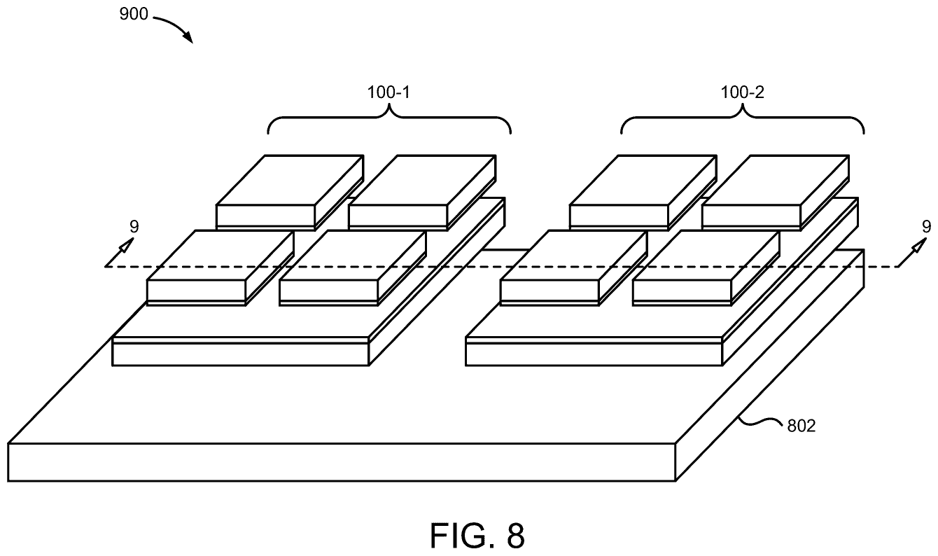

FIG. 8 is a perspective view of an IC device 800 that includes multiple instances of IC device 100, illustrated here as IC devices 100-1 and 100-2, that communicate with one another via a super interposer substrate 802, according to an embodiment.

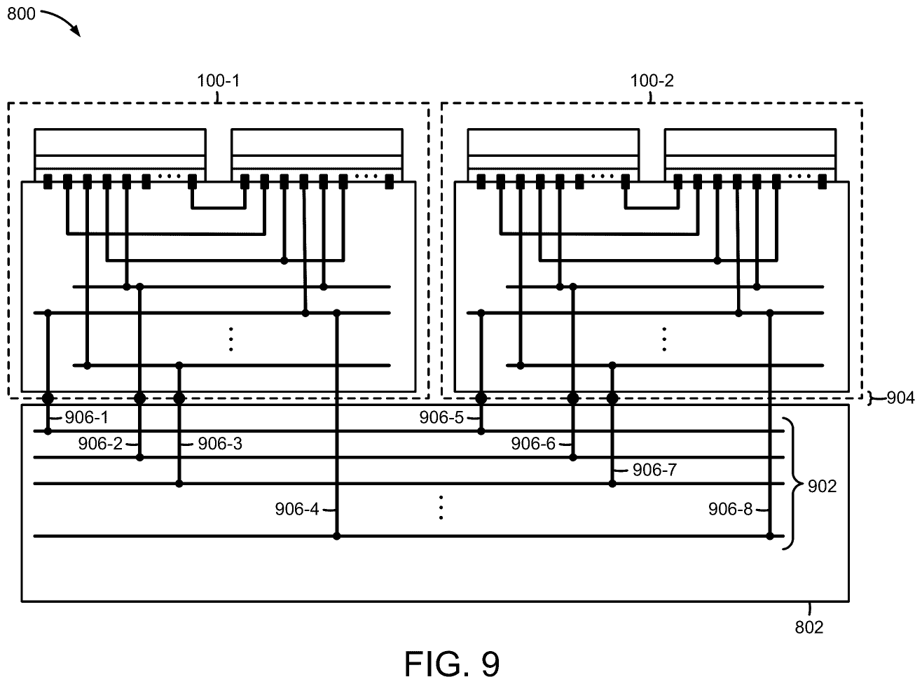

FIG. 9 is a cross-sectional side view of IC device 800 in which super interposer substrate 802 includes one or more metal layers 902 and electrical connections 906 between metal layers 902 and μbumps 904, according to an embodiment. Metal layers 902 may be patterned to provide inter-die connections between IC devices 100-1 and 100-2 and/or to provide/distribute power, a clock(s), and/or configuration parameters to IC devices 100-1 and/or IC devices 100-2.

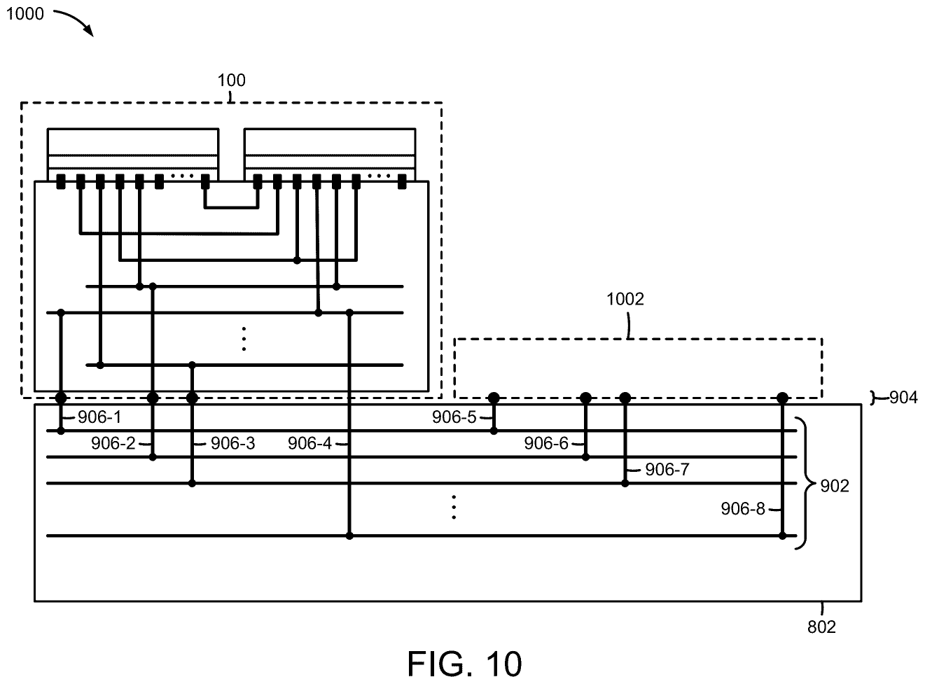

FIG. 10 is a cross-sectional side view of an IC device 1000 that includes IC device 100, super interposer substrate 802 of FIGS. 8 and 9, and a region 1002 in which another IC device may be mounted (e.g., a high-bandwidth memory (HBM) device or other 3^{rd} party IC device), according to an embodiment.

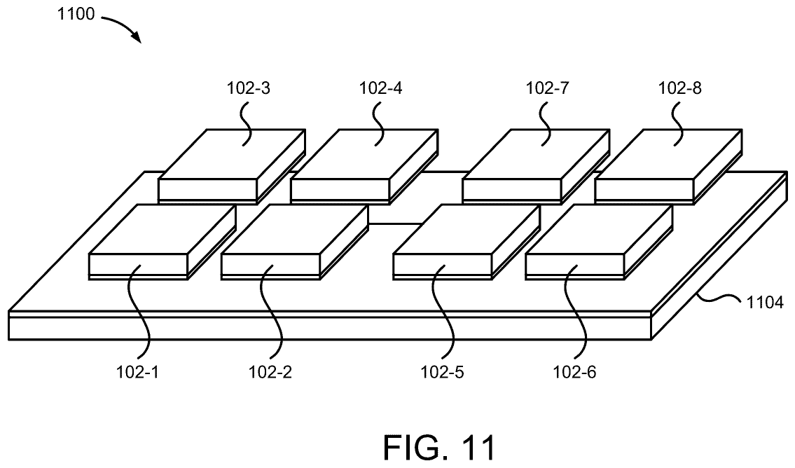

FIG. 11 is a perspective view of an IC device 1100 that includes a 4×2 arrangement of dies 102-1 through 102-8 that communicate with one another via an interposer substrate 1104, according to an embodiment. Dies 102 and interposer substrate 1104 may include respective hybrid bonding connectors, and interposer substrate 1104 may include patterned metal layers and electrical connections that provide inter-die connections amongst dies 102, intra-die connections within dies 102, and/or that provide/distribute power, a clock(s) and/or configuration parameters to dies 102, such as described in one or more examples above.

Features disclosed above with reference to FIGS. 1-11 may be used alone and/or in various combinations with one another.

In one or more of the foregoing examples, die(s) 102 may include one or more of a variety of types of configurable circuit blocks, such as described below with reference to FIG. 12. FIG. 12 is a block diagram of a configurable circuitry 1200, including an array of configurable or programmable circuit blocks or tiles, according to an embodiment. The example of FIG. 12 may represent a field programmable gate array (FPGA) and/or other IC device(s) that utilizes configurable interconnect structures for selectively coupling circuitry/logic elements, such as complex programmable logic devices (CPLDs).

In the example of FIG. 12, the tiles include multi-gigabit transceivers (MGTs) 1201, configurable logic blocks (CLBs) 1202, block random access memory (BRAM) 1203, input/output blocks (IOBs) 1204, configuration and clocking logic (Config/Clocks) 1205, digital signal processing (DSP) blocks 1206, specialized input/output blocks (I/O) 1207 (e.g., configuration ports and clock ports), and other programmable logic 1208, which may include, without limitation, digital clock managers, analog-to-digital converters, and/or system monitoring logic. The tiles further includes a dedicated processor 1210.

One or more tiles may include a programmable interconnect element (INT) 1211 having connections to input and output terminals 1220 of a programmable logic element within the same tile and/or to one or more other tiles. A programmable INT 1211 may include connections to interconnect segments 1222 of another programmable INT 1211 in the same tile and/or another tile(s). A programmable INT 1211 may include connections to interconnect segments 1224 of general routing resources between logic blocks (not shown). The general routing resources may include routing channels between logic blocks (not shown) including tracks of interconnect segments (e.g., interconnect segments 1224) and switch blocks (not shown) for connecting interconnect segments. Interconnect segments of general routing resources (e.g., interconnect segments 1224) may span one or more logic blocks. Programmable INTs 1211, in combination with general routing resources, may represent a programmable interconnect structure.

A CLB 1202 may include a configurable logic element (CLE) 1212 that can be programmed to implement user logic. A CLB 1202 may also include a programmable INT 1211.

A BRAM 1203 may include a BRAM logic element (BRL) 1213 and one or more programmable INTs 1211. A number of interconnect elements included in a tile may depends on a height of the tile. A BRAM 1203 may, for example, have a height of five CLBs 1202. Other numbers (e.g., four) may also be used.

A DSP block 1206 may include a DSP logic element (DSPL) 1214 in addition to one or more programmable INTs 1211. An IOB 1204 may include, for example, two instances of an input/output logic element (IOL) 1215 in addition to one or more instances of a programmable INT 1211. An I/O pad connected to, for example, an I/O logic element 1215, is not necessarily confined to an area of the I/O logic element 1215.

In the example of FIG. 12, config/clocks 1205 may be used for configuration. clock, and/or other control logic. Vertical columns 1209 may be used to distribute clocks and/or configuration signals.

A logic block (e.g., programmable of fixed-function) may disrupt a columnar structure of configurable circuitry 1200. For example, processor 1210 spans several columns of CLBs 1202 and BRAMs 1203. Processor 1210 may include one or more of a variety of components such as, without limitation, a single microprocessor to a complete programmable processing system of microprocessor(s), memory controllers, and/or peripherals.

Configurable circuitry 1200 further includes analog circuits 1250, which may include, without limitation, one or more analog switches, multiplexers, and/or de-multiplexers. Analog switches may be useful to reduce leakage current.

FIG. 12 is provided for illustrative purposes. Configurable circuitry 1200 is not limited to numbers of logic blocks in a row, relative widths of the rows, numbers and orderings of rows, types of logic blocks included in the rows, relative sizes of the logic blocks, illustrated interconnect/logic implementations, or other example features of FIG. 12.

FIG. 13 is a plan view of an IC device 1300 in which a FPGA (e.g., configurable circuitry 1200) is distributed amongst multiple heterogeneous chiplets, or dies 1302-1 through 1302-8 (collectively, dies 1302) that communicate with one another via hybrid bonding connectors and patterned metal layers of an interposer substrate 1304 in a protocol (e.g., a non-serialized protocol) that is native to the FPGA, according to an embodiment.

Die 1302-1 may include a processor, such as processor 1210 in FIG. 12. Die 1302-2 may include memory, such as BRAMs 1203 in FIG. 12 DRAM. Dies 1302-3 and 1302-4 may include input/output (IO) circuitry that interfaces between one or more other dies 1302 and an external device. The IO circuitry may include, for example, multi-gigabit transceivers (MGTs) 1201, IOBs 1204, and/or specialized IO blocks 1207 of FIG. 12. The IO circuitry may include SERDES circuitry (i.e., that interfaces between one or more other dies 1302 and the external device).

Dies 1302-5 through 1302-8 may include other FPGA circuitry, such as CLBs 1202, programmable logic 1208, DSP blocks 1206, and/or analog circuits 1250 of FIG. 12. Dies 1302-5 through 1302-8 may include remaining circuitry of FIG. 12 (e.g., analog circuits 1250 in FIG. 12).

One or more other FPGA elements (e.g., remaining elements of FIG. 12) may be allocated to one or more dies 1302. Clock power distribution circuitry may be distributed amongst dies 1302.

Dies 1302 includes respective hybrid bonding connectors. In the example of FIG. 13, die 1302-1 includes edge-based hybrid bonding connectors 1306 for C2C communications with other ones of dies 1302, and hybrid bonding connectors 1308 within a central region of die 1302-1 for intra-die connections (i.e., communications/clocks routed through interposer substrate 1304) and/or to receive power, clock, and/or configurable parameter distribution from interposer substrate 1304. Dies 1302-2 through 1302-8 may have similar hybrid bonding connectors.

Dies 1302 may communicate with one another via edge-based hybrid bonding connectors 1306 and patterned metal layers of interposer substrate 1304, such as described further above with reference to FIGS. 4 and 5. Dies 1302, or a subset thereof, may include driver circuitry (e.g., buffers and/or flip-flops) that drive C2C communications through edge-based hybrid bonding connectors 1306. The driver circuitry may involve relatively negligible additional circuitry, area, and power.

In an embodiment, hybrid bonding connectors 1306 and 1308 have pitches of approximately 10 μ, or less. In an embodiment, the patterned metal layers of interposer substrate 1304 include more than 1000 tracks per millimeter (e.g., more than 1600 tracks per millimeter, more than 2800 tracks per millimeter, more than 3500 tracks per millimeter, and beyond). In an embodiment, hybrid bonding connectors 1306 and 1308 and the patterned metal layers of interposer substrate 1304 are configured to provide more than 1000 inter-die (i.e., C2C) connections per millimeter (e.g., more than 1600 tracks per millimeter, more than 2800 tracks per millimeter, more than 3500 tracks per millimeter, and beyond). Such densities of hybrid bonding connectors and tracks of metal layers of interpose substrate 1304 may provide ample C2C connections to permit division of an FPGA into numerous chiplets, without necessitating serialized and/or interleaving C2C communications.

Interposer substrate 1304 may further include one or more embedded dies, such as described further above with reference to embedded die 602 in FIG. 6. The embedded die(s) may include FPGA circuitry and/or other circuitry.

IC device 1300 may be mounted on a package substrate, and the package substrate may be mounted on a circuit board, such as described further above with reference to FIG. 7.

In an embodiment, an IC package includes multiple instances of IC device 1300 that communicate with one another via a super interposer substrate, such as described further above with reference to FIGS. 8 and 9. In an embodiment, the super interposer substrate includes a region configured to receive one or more additional IC devices, such as described further above with reference to region 1002 in FIG. 10.

Example hybrid bonding techniques are described below with reference to FIGS. 14A and 14B.

FIG. 14A is a cross-sectional side view of a portion of a die 1402 and a portion of a substrate 1404 that include respective hybrid bonding connectors embedded within a non-conductive material, according to an embodiment. The illustrated portions of die 1402 and substrate 1404 are not drawn to scale. FIG. 14B is a cross-sectional side view of an IC device 1400 in which die 1402 and substrate 1404 are bonded to one another, according to an embodiment.

Die 1402 includes active layers 1406, metal layers 1408, and a hybrid bonding layer 1410. Hybrid bonding layer 1410 includes metal pillars 1412-1 and 1412-2 (e.g., copper) embedded within a non-conductive material 1414 (e.g., silicon dioxide or a polymer). Pillars 1412-1 and 1412-2 are coupled to respective metal-filled vias 1416-1 and 1416-2. In the example of FIG. 14A, metal-filled via 1416-1 is connected to one of active layers 1406, and metal-filled via 1416-2 is connected to one of metal layers 1408.

Substrate 1404 includes a non-conductive layer 1430 (e.g., silicon dioxide) and a hybrid bonding layer 1432. Hybrid bonding layer 1432 includes metal pillars 1434-1 and 1434-2 embedded within a non-conductive material 1438 (e.g., silicon dioxide or a polymer). Pillars 1434-1 and 1434-2 are coupled to respective metal-filled vias 1436-1 and 1436-2. Metal-filled vias 1436-1 and 1436-2 may extend through an entirety of substrate 1404 (i.e., through-silicon-vias, or TSVs). Alternatively, where substrate 1404 is to serve as an interposer substrate, substrate 1404 may include one or more metal layers, and metal-filled vias 1436-1 and 1436-2 may be coupled to one of more of the metal layers, such as described in one or more examples further above.

In FIG. 14A, surfaces 1418-1 and 1418-2 of pillars 1412-1 and 1412-2 extend through a surface 1420 of die 1402 and hybrid bonding layer 1410. Similarly, surfaces 1440-1 and 1440-2 of pillars 1434-1 and 1434-2 extend through a surface 1442 of substrate 1404 and hybrid bonding layer 1432. When surfaces 1420 and 1442 are placed in contact with one another (e.g., bonded to one another), pillar surfaces 1418-1 and 1418-2 are in contact with respective pillar surfaces 1440-1 and 1440-2, such as illustrated in FIG. 14B.

In an embodiment, an electronic design automation (EDA) place and route tool is designed to consider routing an intra-die signal(s) (e.g., data communications, clocks, and/or controls) through an interposer substrate, as an alternative to routing the intra-die signal through the die, such as to relieve congestion and/or to provide a shorter route.

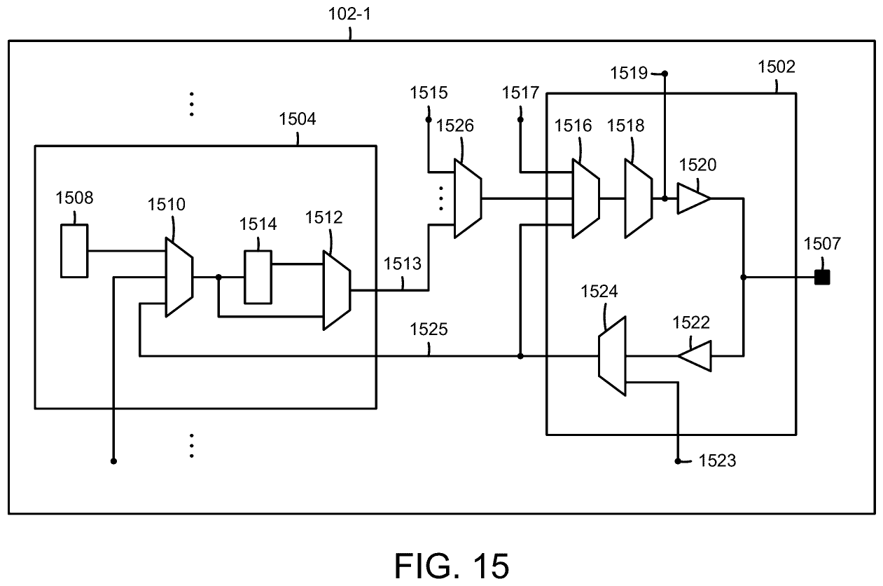

FIG. 15 is a circuit diagram of die 102-1 including an input/output (IO) circuit 1502 that permits a circuit block 1504 of die 102-1 to communicate with another circuit block of die 102-1 and/or with an off-die device (e.g., another one of dies 102) via a hybrid bonding connector 1507, using a non-serialized protocol native to circuit block 1504, according to an embodiment.

In the example of FIG. 15, circuit block 1504 includes functional circuitry 1508, multiplexers 1510 and 1512, and a flip-flop 1514. Circuit block 1504 may represent, for example, a configurable logic block (CLE) of an FPGA, and functional circuitry 1508 may include a look-up table (LUT).

An output path of IO circuit 1502 includes multiplexers 1516 and 1518, and a driver 1520. An input path of IO circuit 1502 includes a driver 1522 and a multiplexer 1524. Multiplexer 1524 provides input received at hybrid bonding connector 1507, or an input 1523 (e.g., an input received at another hybrid bonding connector) to an input 1525 of circuit block 1504.

IC die 106 may include a multiplexer 1526 that provides an output 1513 of circuit block 1504 or an output 1515 of another circuit block of IC die 1506 to multiplexer 1516.

Multiplexer 1516 provides the output of multiplexer 1526, an input 1517 (e.g., from another circuit block of die 1506, or the output of multiplexer 1524 to multiplexer 1518. An output of multiplexer 1518 is provided to driver 1520, and may also be provided to a redundant driver via a terminal 1519.

Driver 1520 and 1522 may include tristate devices that provide a high impedance state such that only one of drivers 1520 and 1522 is electrically coupled to hybrid bonding connector 1517 at a time.

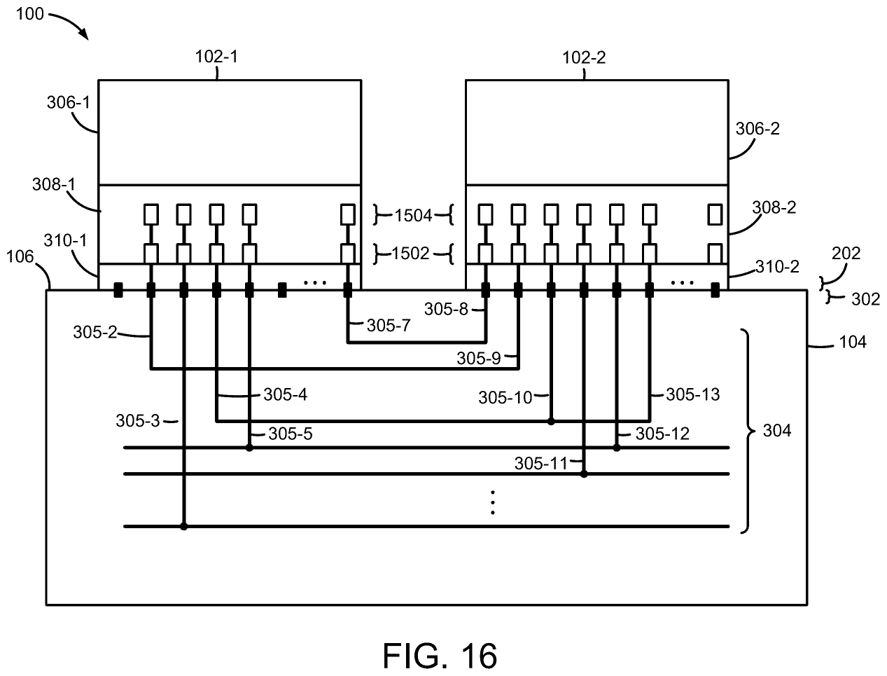

FIG. 16 is a block diagram of IC device 100, as illustrated in FIG. 5, in which dies 102-1 and 102-2 include multiple circuit blocks 1504 and associated IO circuits 1502, according to an embodiment.

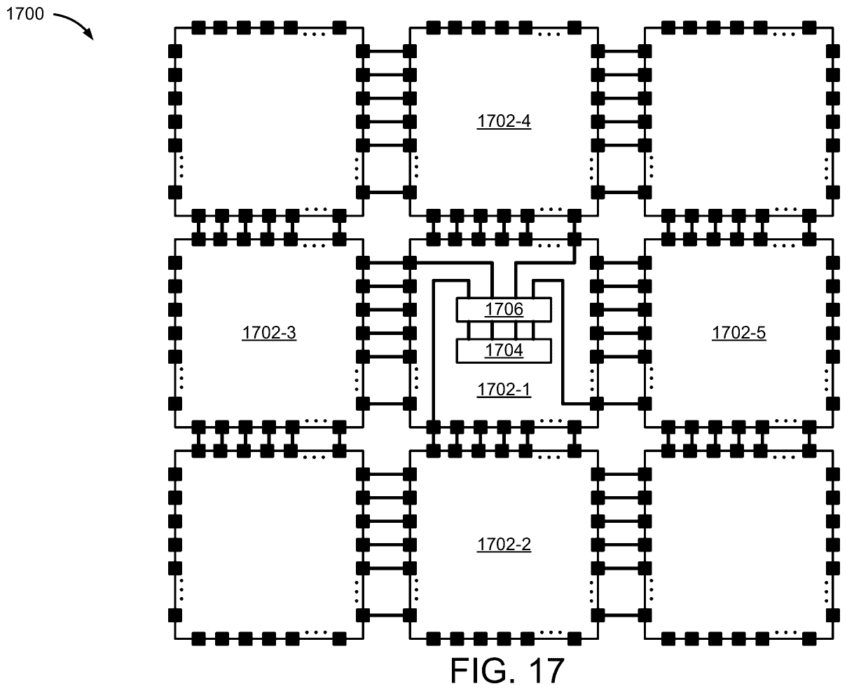

FIG. 17 is a block diagram of an IC device 1700 that includes a die 1702-1 having a functional circuit 1704 that communicates with adjacent dies 1702-2 through 1702-5 in a symmetrical fashion, via an IO circuit 1706 and hybrid bonding connectors, according to an embodiment. Dies 1702-2 through 1702-5 may be referred to as south, west, north, and east, respectively, relative to die 1702-1.

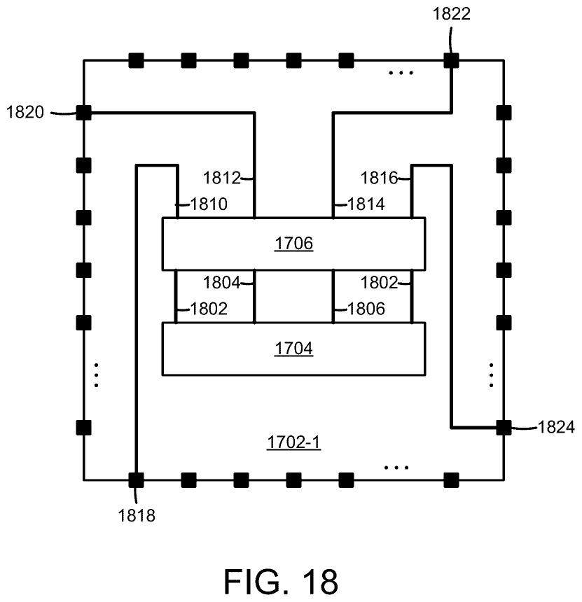

FIG. 18 is an expanded view of die 1702-1, in which communication paths between functional circuit 1704 and IO circuit 1704 include paths 1802 through 1808, and communication paths between IO circuit 1704 and hybrid bonding connectors 1818 through 1824 include paths 1810 through 1816. according to an embodiment.

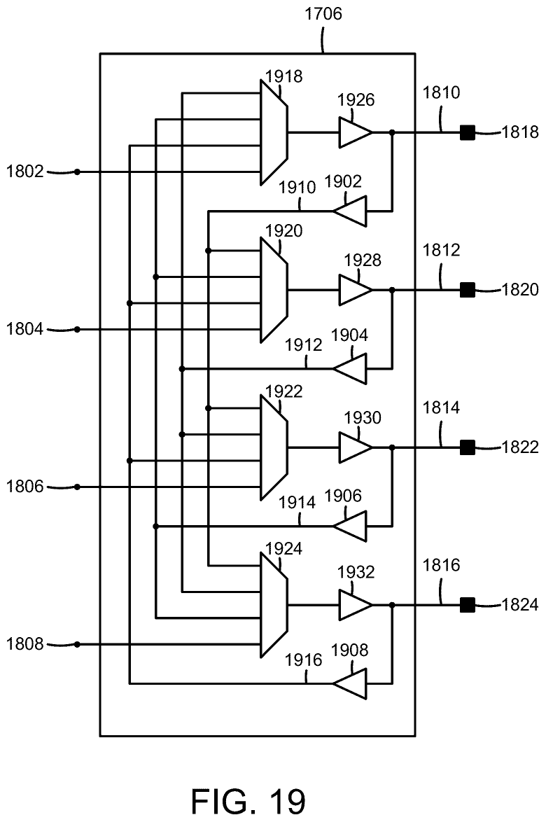

FIG. 19 is a circuit diagram of IO circuit 1704, according to an embodiment. In the example of FIG. 19. IO circuit 1704 includes input drivers 1902 through 1908 that drive inputs received at respective hybrid bonding connectors 1818 through 1824, to respective lines 1910 through 1916. IO circuit 1704 further includes multiplexers 1918 through 1924 and output drivers 1926 through 1932.

Multiplexer 1918 provides output 1802 of functional circuit 1704, or the input received at one of hybrid bonding connectors 1820 through 1844 to hybrid bonding connector 1818 via output driver 1926.

Multiplexer 1920 provides output 1804 of functional circuit 1704, or the input received at one of hybrid bonding connectors 1818, 1822, and 1824 to hybrid bonding connector 1820 via output driver 1928.

Multiplexer 1922 provides output 1806 of functional circuit 1704, or the input received at one of hybrid bonding connectors 1818, 1820, and 1824 to hybrid bonding connector 1822 via output driver 1930.

Multiplexer 1924 provides output 1808 of functional circuit 1704, or the input received at one of hybrid bonding connectors 1818 through 1822 to hybrid bonding connector 1824 via output driver 1932.

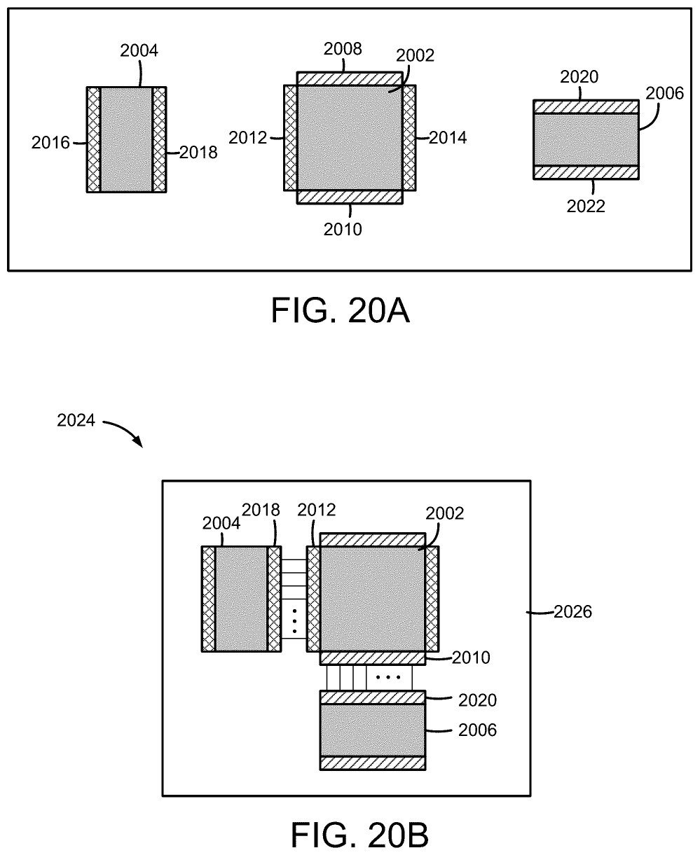

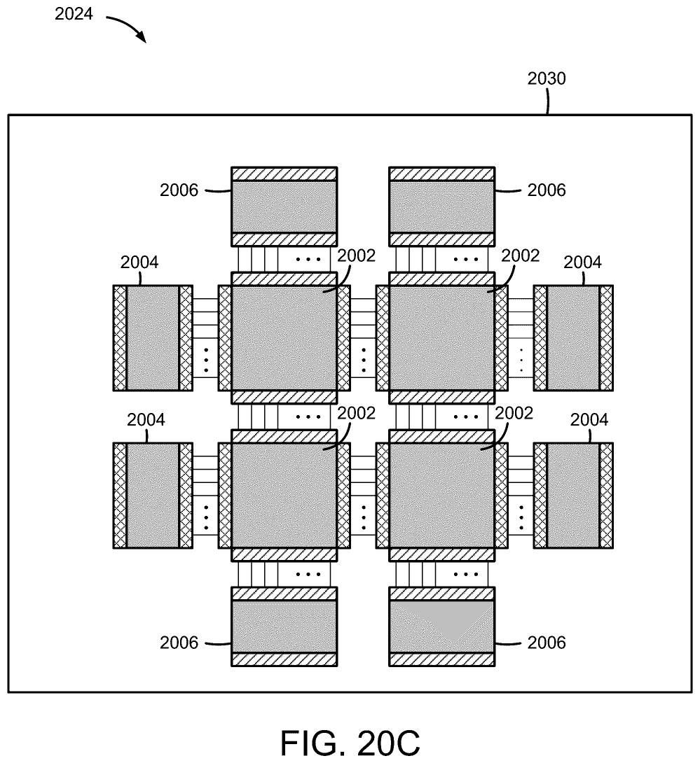

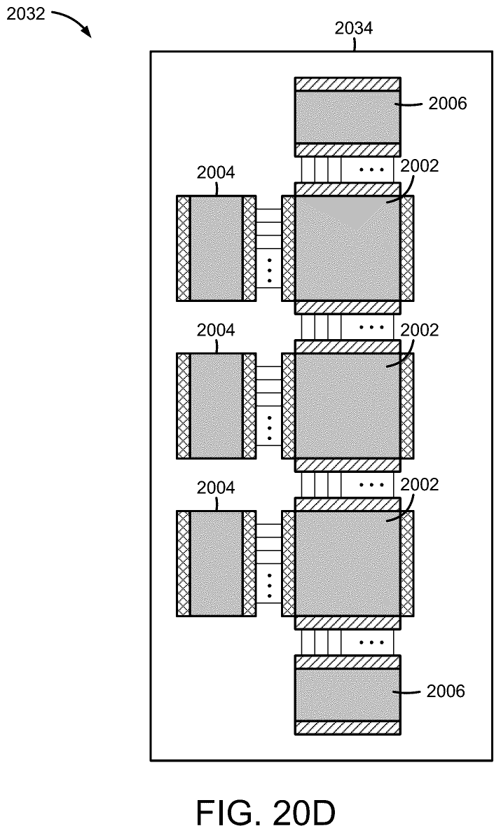

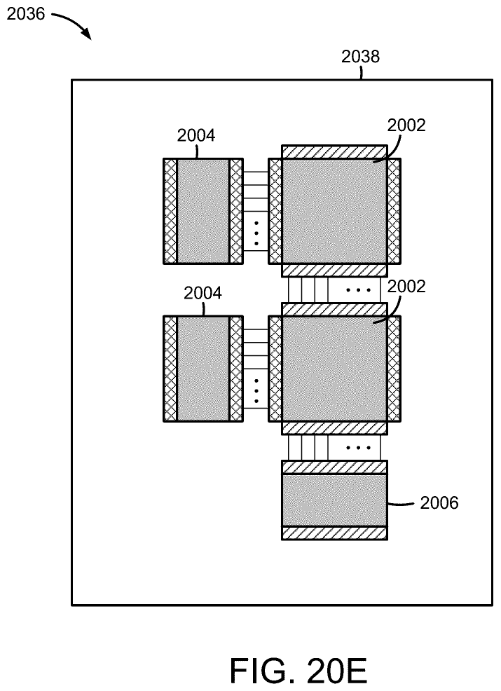

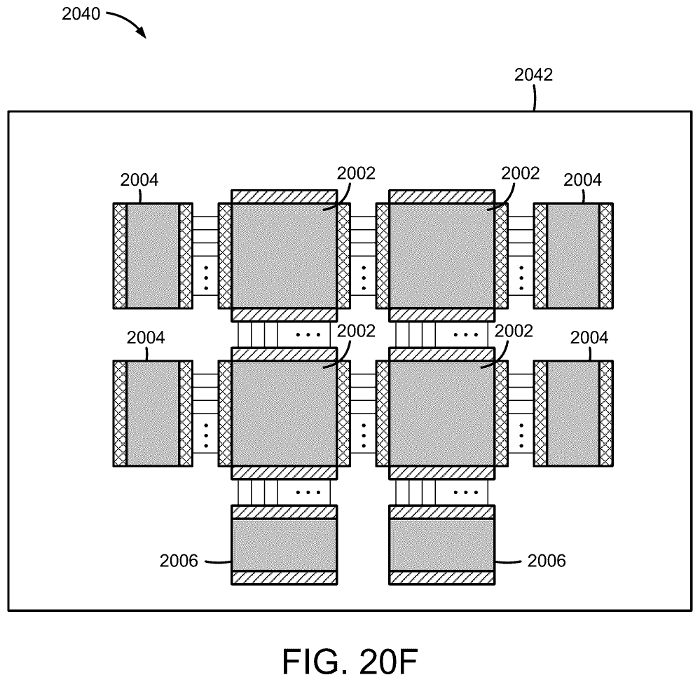

In an embodiment, a set of dies may be designed to be readily combinable in various numbers and arrangements, such as to provide a family of IC devices. The set of dies may include, for example a core die or a core set of dies (e.g., a FPGA die or set of FPGA dies), and one or more peripheral dies or chiplets (e.g., an IO die and a GT die). The set of dies may include symmetrical hybrid bonding edge connectors, such as described above with reference to FIGS. 17-19, examples of which are provided below with reference to FIGS. 20A through 20F.

FIG. 20A is a block diagram of a set of dies that includes a core die 2002 (e.g., a FPGA die), a first peripheral die 2004 (e.g., an IO die), and a second peripheral die 2004 (e.g., a gigabit transceiver or GT die), according to an embodiment. Core die 2002 includes hybrid bonding edge connectors 2008, 2010, 2012, and 2014 along respective edges of core die 2002. First peripheral die 2004 includes hybrid bonding edge connectors 2016 and 2018 along opposing edges of peripheral die 2004 that are symmetrical (i.e., matching) with hybrid bonding edge connectors 2012 and 2014 of core die 2002. Second peripheral die 2006 includes hybrid bonding edge connectors 2020 and 2022 along opposing edges of peripheral die 2006 that are symmetrical with hybrid bonding edge connectors 2008 and 2010 of core die 2002.

FIG. 20B is a block diagram of an IC device 2024 that includes core die 2002, first peripheral die 2004, and second peripheral die 2206, according to an embodiment. In the example of FIG. 20B, hybrid bonding edge connectors 2018 and 2012 are connected to one another via an interposer substrate 2026, and hybrid bonding edge connectors 2010 and 2020 are connected to one another via interposer substrate 2026.

FIG. 20C is a block diagram of an IC device 2028 that includes four core dies 2002, four first peripheral dies 2004, and four second peripheral dies 2206, interconnected via an interposer substrate 2030, according to an embodiment.

FIG. 20D is a block diagram of an IC device 2032 that includes three core dies 2002, three first peripheral dies 2004, and two second peripheral dies 2206. interconnected via an interposer substrate 2034, according to an embodiment.

FIG. 20E is a block diagram of an IC device 2036 that includes two core dies 2002, two first peripheral dies 2004, and one second peripheral die 2206, interconnected via an interposer substrate 2038, according to an embodiment.

FIG. 20F is a block diagram of an IC device 2040 that includes four core dies 2002, four first peripheral dies 2004, and two second peripheral dies 2206, interconnected via an interposer substrate 2042, according to an embodiment.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit.” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture. functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations. the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. An integrated circuit (IC) device, comprising:
an interposer substrate comprising a plurality of metal layers, a plurality of hybrid bonding connectors exposed through a surface of the interposer substrate, and electrical connections between the hybrid bonding connectors of the interposer substrate and the metal layers; and
a field-programmable gate array (FPGA) distributed amongst multiple IC dies disposed on the surface of the interposer substrate;
wherein the multiple IC dies comprise respective hybrid bonding connectors exposed through surfaces of the respective IC dies in alignment with the hybrid bonding connectors of the interposer substrate;
wherein the metal layers are patterned to provide inter-die communications amongst the multiple IC dies; and
wherein the IC dies are configured to communicate with one another via the hybrid bonding connectors of the respective IC dies and the hybrid bonding connectors, the patterned metal layers, and the electrical connections of the interposer substrate.

2. The IC device of claim 1, wherein the IC dies are further configured to communicate with one another via the hybrid bonding connectors of the respective IC dies and the hybrid bonding connectors, the patterned metal layers, and the electrical connections of the interposer substrate, using a non-serialized protocol native to the FPGA

3. The IC device of claim 2, wherein:
the hybrid bonding connectors of the IC dies comprise hybrid bonding connectors along one or more edges of the surfaces of the IC dies; and
the IC dies are further configured to communicate with one another via the hybrid bonding connectors along the edges of the surfaces of the IC dies, the patterned metal layers of the interposer substrate, and the electrical connections, using the non-serialized protocol native to the FPGA.

4. The IC device of claim 3, wherein the IC dies further comprise buffers configured to buffer inter-die communications amongst the IC dies.

5. The IC device of claim 4, wherein the IC dies further comprise flip-flops configured to drive the inter-die communications amongst the IC dies.

6. The IC device of claim 3, wherein the IC dies are further configured to communicate synchronously with one another via the hybrid bonding connectors along the edges of the IC dies, the patterned metal layers of the interposer substrate, and the electrical connections, using the non-serialized protocol native to the FPGA.

7. The IC device of claim 1, wherein:
the hybrid bonding connectors of the IC dies comprise hybrid bonding connectors within central regions of the surfaces of the IC dies; and
the metal layers are further patterned to provide intra-die communications within the respective IC dies through the hybrid bonding connectors within the central regions of the surfaces of the respective IC dies.

8. The IC device of claim 1, wherein:
the hybrid bonding connectors of the IC dies comprise hybrid bonding connectors within central regions of the surfaces of the IC dies; and
the metal layers are further patterned to provide one or more of power, a clock, and configuration parameters to the IC dies through the hybrid bonding connectors within the central regions of the surfaces of the IC dies.

9. The IC device of claim 1, wherein:
a first one of the IC dies comprises a processor of the FPGA;
a second one of the IC dies comprises memory of the FPGA;
a third one of the IC dies comprises input/output (IO) circuitry of the FPGA configured to interface between the FPGA and one or more external devices;
a fourth one of the IC dies comprises configurable logic of the FPGA.

10. The IC device of claim 1, wherein:
the hybrid bonding connectors of the interposer substrate and the IC dies have pitches of approximately 10 μ, or less.

11. The IC device of claim 1, wherein:
the hybrid bonding connectors of the interposer substrate and the IC dies, and the patterned metal layers of the interposer substrate are configured to provide more than 1000 inter-die connections per millimeter.

12. The IC device of claim 10, wherein:
the hybrid bonding connectors of the interposer substrate and the IC dies, and the patterned metal layers of the interposer substrate are configured to provide more than 1600 inter-die connections per millimeter.

13. The IC device of claim 10, wherein:
the hybrid bonding connectors of the interposer substrate and the IC dies, and the patterned metal layers of the interposer substrate are configured to provide more than 2800 inter-die connections per millimeter.

14. The IC device of claim 10, wherein:
the hybrid bonding connectors of the interposer substrate and the IC dies, and the patterned metal layers of the interposer substrate are configured to provide more than 3600 inter-die connections per millimeter.

15. An integrated circuit (IC) device, comprising:
an interposer substrate comprising a plurality of metal layers, a plurality of hybrid bonding connectors exposed through a surface of the interposer substrate, and electrical connections between the hybrid bonding connectors of the interposer substrate and the metal layers; and
multiple IC dies disposed on the surface of the interposer substrate;
wherein the IC dies comprise respective hybrid bonding connectors exposed through surfaces of the respective IC dies in alignment with the hybrid bonding connectors of the interposer substrate;
wherein the metal layers are patterned to provide inter-die communications amongst the multiple IC dies;
wherein a first one of the IC dies is configured to communicate with one or more other ones of the IC dies via the hybrid bonding connectors of the respective IC dies and the hybrid bonding connectors, electrical connections, and patterned metal layers of the interposer substrate.

16. The IC device of claim 15, wherein the metal layers are further patterned to provide one or more of power, a clock, and configuration parameters to one or more of the IC dies via the electrical connections and hybrid bonding connectors of the interposer substrate and the hybrid bonding connectors of the respective one or more IC dies.

17. The IC device of claim 16, wherein the metal layers and the hybrid bonding connectors of the interposer substrate are further configured to distribute one or more of the power and the clock to multiple hybrid bonding connectors of the one or more IC dies.

18. The IC device of claim 15, wherein:
the hybrid bonding connectors of the first IC die comprise hybrid bonding connectors along an edge of the surface of the first IC dies and hybrid bonding connectors within a central region of the surface of the first IC die;
the first IC die comprises components of a field programmable gate array (FPGA) and is further configured to communicate with the one or more other ones of the IC dies via the hybrid bonding connectors along the edge of the surface of the first IC die, using a non-serialized protocol native to the FPGA;
the metal layers are further patterned to provide intra-die communications within the first IC die through the hybrid bonding connectors within the central region of the surface of the first IC die; and
the interposer substrate is configured to provide one or more of power, a clock, and configuration parameters to the first IC die through the hybrid bonding connectors within the central region of the surface of the first IC die.

19. The IC device of claim 15, wherein the interposer substrate is configured to route a clock from a first node of the first IC die to a second node of the first IC die.

20. An integrated circuit (IC) device, comprising:
an interposer substrate comprising a plurality of metal layers, a plurality of hybrid bonding connectors exposed through a surface of the interposer substrate, and electrical connections between the hybrid bonding connectors of the interposer substrate and the metal layers; and
a plurality of field-programmable gate array (FPGA) chiplets disposed on the surface of the interposer substrate;
wherein the FPGA chiplets comprise respective hybrid bonding connectors exposed through surfaces of the respective FPGA chiplets in alignment with the hybrid bonding connectors of the interposer substrate;
wherein the metal layers are patterned to provide inter-die communications amongst the FPGA chiplets; and
wherein the FPGA chiplets are configured to communicate with one another via the hybrid bonding connectors of the respective FPGA chiplets and the hybrid bonding connectors, patterned metal layers, and electrical connections of the interposer substrate.
